(19) United States
(12) Patent Application Publication
(10) Pub. No.: US 2008/0072691 A1
(43) Pub. Date: Mar. 27, 2008

(54) Method and System for Generating Control Signals for Controlling a Controllable Device

(75) Inventor: Thomas Gruber, Gols (AT)

Correspondence Address: PHILIPS INTELLECTUAL PROPERTY & STANDARDS, P.O. BOX 3001, BRIARCLIFF MANOR, NY, 10510, US

(73) Assignee: KONINKLIJKE PHILIPS ELECTRONICS, N.V., EINDHOVEN (NL)

(21) Appl. No.: 11/570,047

(22) PCT Filed: Jun. 7, 2005
(86) PCT No.: PCT/IB05/51853

§ 371 Date: Dec. 5, 2006

(30) Foreign Application Priority Data
Jun. 10, 2004 (EP) 04102637.8

(51) Int. Cl. G01R 27/08; G01D 21/00; G01R 35/00

(52) U.S. Cl. 73/865.4; 324/601; 324/692

(57) ABSTRACT

In such a method and system, firstly, at least an electrically conducting first connection to a first body area (3a) of the whole body of a living being is established and at least an electrically conducting second connection to a second body area (3b) of the whole body of the living being at a distance from the first body area (3a) and, secondly, a change takes place in the physical relation between at least one body part (1, 2) of the whole body and the whole body, which change in the physical relation causes a change to occur in the impedance value of a bioelectrical impedance, which bioelectrical impedance is present between the first body area (3a) and the second body area (3b) and, thirdly, a detection takes place of the change in the impedance value of said bioelectrical impedance, as a result of which occurrence of the change result information (RI) is obtained and, fourthly, the control signal (CTRS) is generated in dependence on the result information (RI).

### FIELD OF THE INVENTION

The invention relates to a method for generating at least one control signal for controlling a controllable device, in which method at least an electrically conducting first connection is established to a first body area of the whole body of a living being and an electrically conducting second connection is established to a second body area of the whole body of the living being, at a distance from the first body area.

The invention further relates to a system for generating at least one control signal for controlling a controllable device, with at least an electrically conducting first contact for establishing at least an electrically conducting first connection to a first body area of the whole body of a living being and with at least an electrically conducting second contact for establishing at least an electrically conducting second connection to a second body area of the whole body of the living being, at a distance from the first body area. The invention further relates to an application of such a method and such a system for remote control of an electrical device.

### BACKGROUND OF THE INVENTION

A method as well as a system of the type described in the opening paragraph are known, for example, from U.S. Pat. No. 5,016,213. In this known method and this known system, a change in the galvanic skin resistance is determined for a user of a controllable device, which controllable device is an entertainment electronics device in this case. This determined change in skin resistance is used, for example, for controlling a game while using entertainment electronics. The known system comprises a separate part made of an insulating material, in which part is placed a first contact and a second contact at a distance from each other. To determine the change in skin resistance, an electrically conducting first connection must be established to a first body area of the user and an electrically conducting second connection to a second body area of the whole body of the user at a distance from the first body area. Establishing these connections takes place here in such a manner that the user touches the first contact mentioned earlier with a first finger of his hands and the second contact with a second finger of his hands (with direct skin contact in each case).

Many users can partially change their skin resistance consciously by suitable mental training and thus use such a change in skin resistance for controlling the entertainment electronics device for conducting the game.

A disadvantage observed in this known method and this known system is that, as already pointed out earlier, suitable mental training is needed for conducting this known method, where really assessable differences or conscious changes in the skin resistance can be achieved by only a limited number of users, so that such changes in the galvanic resistance can deliberately be brought into practice by the user of the electrical device to control the device. Furthermore, it is disadvantageous that there are normally large fluctuations in the skin resistance of an individual or user of an electrical device, so that a direct use of the known method and of the known system is not possible without prior matching or balancing, as the case may, for the user employing the known method. Another disadvantage of the known method is that, considering the partly large differences in the absolute values of the skin resistance of a user, it is difficult to use uniform method parameters in the known method for controlling a device.

### OBJECT AND SUMMARY OF THE INVENTION

It is an object of the invention to provide a method of the type as defined in the opening paragraph and a system of the type defined in the second paragraph and a use of the method as well as of the system, in which the above-mentioned disadvantages are avoided and the method as invented as well as the system as invented can be used for any user of a controllable device, for example an electrical device, for generating at least a control signal for controlling the controllable device, especially irrespective of any mental or other training.

In order to achieve the above-mentioned object, the features as invented have been provided in a method as invented, such that a method as invented can be characterized in the manner mentioned below, namely:

Method for generating at least one control signal for controlling a controllable device, in which method at least an electrically conducting first connection is established to a first body area of the whole body of a living being and at least an electrically conducting second connection is established to a second body area of the whole body of the living being, at a distance from the first body area, and a change is made in the physical relation between at least one body part of the whole body and the whole body, which change in the physical relation causes a change in the impedance value of an impedance, which impedance is present between the first body area and the second body area and a detection of the change in the impedance value of said impedance is carried out in which result information is obtained as a result of the occurrence of the change and a generation of the at least one control signal is carried out in relation to the result information.

In order to achieve the above-mentioned object, the features as invented have been provided in a system as invented, so that a system as invented can be characterized in the manner mentioned below, namely:

System for generating at least one control signal for controlling a controllable device, the system comprising at least an electrically conducting first contact for establishing at least an electrically conducting first connection to a first body area of a whole body of a living being and comprising at least an electrically conducting second contact for establishing at least an electrically conducting second connection to a second body area of the whole body of the living being at a distance from the first body area, and comprising detection means for detecting a change in the impedance value of an impedance, which impedance is present between the first body area and the second body area, which change in the impedance value is the result of a change in the physical relation between at least one body part of the whole body and the whole body and results in result information, and the system comprising generating means for generating the control signal in dependence on the result information.

An analysis or determination, as the case may be, of the impedance may generally be used on the basis of the natural cellular structure and taking into consideration the fact that there is generally a large number of cells in a living being or individual, such as for example a user of a controllable device. It is thus possible to talk here about a bioelectrical impedance. The theoretical basis in respect of a bioelectrical impedance of a living being is well known in professional circles; any further discussion in this regard will therefore be dispensed with. As an example, however, a description called “Principles of Bioelectrical Impedance Analysis; Rudolph J. Liedtke (1 Apr. 1997)” that can be obtained through http://www.rjlsystems.com/research/bia-principles.html can be mentioned here in this context.

If an AC power source is contacted with a first body area of an individual or a user of a controllable device by means of an electrically conducting first contact and with a second body area by means of an electrically conducting second contact, and an AC current flows through the human body, the electrical equivalent of a cell or a multiplicity of cells respectively can be regarded as a non-ideal capacitance, from which non-ideal capacitance the resistance values and reactance values can be used for analyses or evaluations. It is easy to imagine that a change in the cells as well as the intra-cellular ground has direct effects on the resistance values and reactance values. Such a change in a cell or several cells can already be triggered by a change in the physical relation of body parts of the user, for example such a change in the physical relation can already be formed by tensioning of muscles or by moving limbs of the user.

This makes it immediately evident that the method a invented as well as the system as invented can be put to direct use in any living being or individual or any user of a controllable device, because in contrast to the current state of the art, for example as has become known from the above-mentioned document U.S. Pat. No. 5,016,213, a mental training for a conscious or willful influence on the skin resistance, which skin resistance can subsequently lead to determination of measured values of the main resistance or its change, is not required.

Furthermore, the basic assumption according to the invention is that for the generation or production of at least one control signal, as proposed by the invention, upon determination of the impedance between the body areas to which the electrically conducting connections have been established when the method as invented as well as the system as invented is used on different individuals, even if there are different users and different absolute values, yet a desired reliable generation of at least one control signal in dependence on the respectively determined impedance value of the impedance can be effected.

According to the measures as claimed in claim 2 or claim 9, as the case may be, the advantage is derived that a simplest possible configuration of the system as invented is achievable for which it is enough to have only one contact pair to establish the electrically conducting connections to two body areas of the user. In addition, determination of a bioelectrical impedance is made possible here, which bioelectrical impedance can be changed by means of simple changes in the physical relation between at least one body part of the whole body and the whole body of the user, for example by simply tensioning a muscle.

According to the measures as claimed in claims 3, 4, 10 and 11, the advantage is derived that very low cabling expenditure is involved and in addition a very simple and reliable detection of changes in the impedance value can be carried out and, in addition, it is easily possible to make repeated changes in the physical relation of the user.

In this context, according to the measures as claimed in claim 5 or in claim 12, another advantage is derived that a simple and easy-to-use definition is possible so that especially when utilizing the system as invented and when carrying out the method as invented, no extra precautions as to operation are to be taken and the freedom of movement of the user is not or hardly hampered by restrictive elements.

According to the measures as claimed in claim 6, the advantage is derived that a change in the physical relation between at least one body part of the whole body and the whole body can be easily carried out for undertaking the control, taking into consideration the impedance simply by easily accessible body areas. These areas are usually sufficiently trained in every user in respect of relative movements of the individual fingers or finger tips, which movements are conscious and perceptible through the sense of touch, where this leads directly to easily assessable values or changes in the determined impedance even with slight relative movements of the fingers or finger tips. In this way, it is possible to make an exact and precise control or regulation through exactly executable and effectible relative movements between the individual fingers or finger tips and/or the palm of the hand and the changes in the determined impedance or the impedance value that can be thereby achieved.

According to the measures as claimed in claim 7 or in claim 13, the advantage is derived that such a comparison or calibration and correlation with a base setting or initial setting of the controllable device makes it possible to further increase the precision in connection to the generation of the control signals and the evaluation especially even of possible minor changes in the bioelectrical impedance of the user of the controllable device.

According to the measures as claimed in claim 14 the advantage is derived that a simple and reliable definition can be made for the at least one current source electrode and the at least one detection electrode, where this can be achieved without undue adverse effect on the freedom of movement of the user.

According to the measures as claimed in claim 15 the advantage is derived that the method as invented can be utilized for a multiplicity of different controllable devices, for example entertainment electronics devices. For example, the system as invented can be made available in the manner of a universally usable remote operation when applying or using the system as invented and possibly matching with different devices to be linked to the system or to be controlled by the system.

According to the measures as claimed in claim 16 the advantage is derived that a multiplicity of parameters of controllable devices can be controlled in connection to the method as invented as well as the system as invented.

### BRIEF DESCRIPTION OF THE DRAWINGS

These and other aspects of the invention are apparent from and will be elucidated below with reference to the non-limitative embodiment(s) described hereinafter.

In the drawings:

FIG. 1 shows a schematic arrangement of a system as invented for carrying out the method as invented, both current source electrodes and detection electrodes being each arranged in the region of an underarm of a user.

FIG. 2 shows a schematically adapted embodiment of the arrangement of a system as invented for carrying out the method as invented, points being shown in the area of finger tips or hand palms for changing the physical relation of a body part to determine the impedance or impedance changes.

FIG. 3 shows a schematic block diagram concerning the detection of the change in the impedance value of said impedance as well as the subsequent generation of a control signal for controlling a controllable device.

FIG. 4 shows an adapted embodiment of an arrangement of the system as invented for carrying out the method as invented, similar to the illustration in FIG. 1, in which detection electrodes are arranged in the area of a finger.

FIG. 5 shows schematically a flow chart for carrying out the method as invented.

FIG. 6 shows a schematic arrangement of another system as invented for carrying out a method as invented, in which current source electrodes as well as detection electrodes are used together.

### DESCRIPTION OF EMBODIMENTS

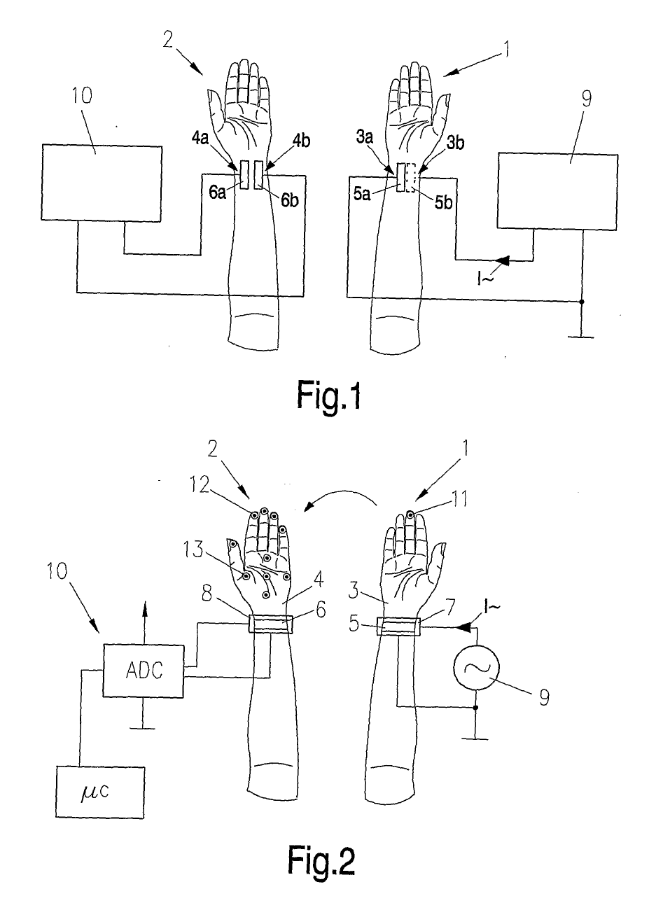

In FIG. 1 and in FIG. 2, the right arm 1 and the left arm 2 of a person not shown in detail are indicated, in which an electrically conducting first contact 5a is provided in the underarm area of the right arm 1 on the inner side of the underarm area and an electrically conducting second contact 5b on the outer side of the underarm area (shown with dashes), by means of which first contact 5a an electrically conducting first connection is established to a first body area of said underarm area and by means of which second contact 5b an electrically conducting second connection is established to a second body area of said underarm area. Furthermore, an electrically conducting third contact 6a and an electrically conducting fourth contact 6b are provided on the left arm 2 in the underarm area on the inner side of the underarm area in essence mutually parallel and at a distance from each other, with the help of which third contact 6a an electrically conducting third connection is established to a third body area of said underarm area and with the help of which fourth contact 6b an electrically conducting fourth connection to a fourth body area of said underarm area is established.

Further, for the sake of simplicity, the first contact 5a together with the second contact 5b will be designated as current source electrodes 5 and the third contact 6a together with the fourth contact 6b as detection electrodes 6.

Instead of the separate arrangement of the current source electrodes 5 shown in FIG. 1 as well as the detection electrodes 6, the current source electrodes 5 are integrated in a first armband 7 and the detection electrodes 6 in a second armband 8 in the illustration shown in FIG. 2, which first armband 7 or second armband 8 respectively is in turn arranged in the underarm area of the respective arm 1 and 2.

FIG. 1 moreover shows a current source 9, by means of which current source 9 in the present case the current source electrodes 5 are operated or fed with a constant AC current I˜ with a frequency f=1 kHz, so there is an AC current flowing through the body areas and the body of the person contacted by the current source electrodes 5. The corresponding power supply 9 is also pointed out in FIG. 2.

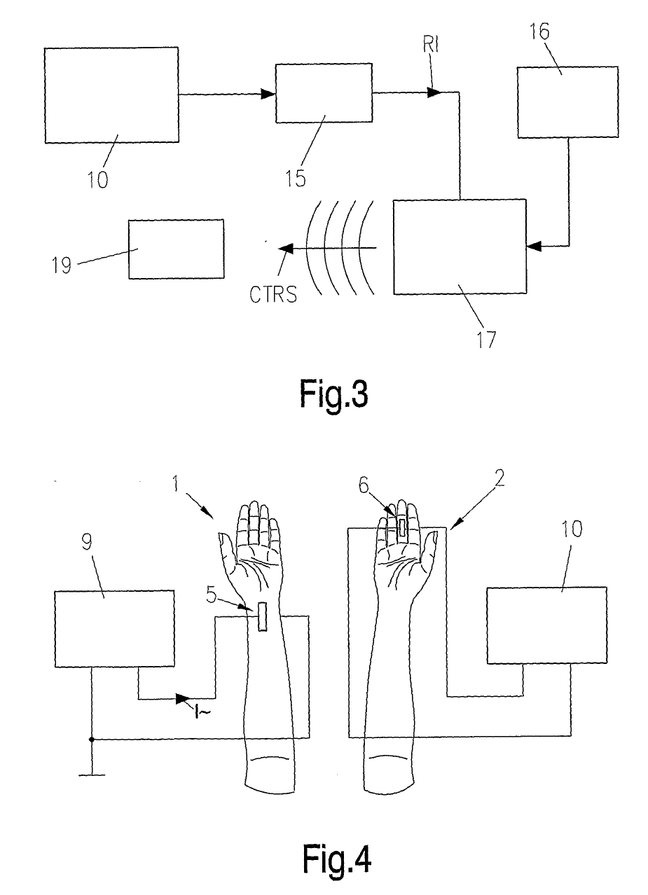

Detection means are provided for determining the impedance or for detecting its change, which detection means are indicated in FIGS. 1 and 2 respectively by means of an impedance measuring device 10, which impedance measuring device 10 is linked to the detection electrodes 6 and delivers either resistance values or capacitance values as measurement results for the impedance of the body areas contacted with the help of the detection electrodes 6. The measurement results are subsequently used for generating a signal, especially a remote control signal for controlling a downstream electrical device, as explained in detail especially with the help of FIG. 3. The impedance measuring device 10 here is a device working by a measuring method known in professional circles for measuring the impedance.

FIG. 2 further shows schematically that for example the finger tip 11 of the middle finger of the right hand, that is to say the hand of the right arm 1, on which right arm 1 the current source electrodes 5 are arranged, is brought into contact with different finger tips 12 of the hand of the left arm 2 (i.e. of the left hand) and thus a change in the physical relation between at least one body part of the whole body and the whole body is carried out, which change in the physical relation results in a change in the impedance value of said impedance, which impedance value of the impedance can be detected by using the impedance measuring device 10. Alternatively, the finger tip 11 of the middle finger of the right hand can for example be brought into contact with different areas or points 13 of the palm of the left hand and/or the finger tip 11 of the right hand can be moved relative to individual fingers, for example along the longitudinal direction of individual fingers or between the points 13 indicated in the area of the palm of the left hand. Different values of the impedance measured by the impedance measuring device 10 yielded by a contact between the tip 11 of the middle finger and/or the tips 12 of the fingers of the left hand and/or areas of the left hand depicted as points 13, where such different measured values, i.e. changes in the measured value here, are used subsequently for generating signals, which are particularly remote control signals for controlling different parameters of a downstream electrical device.

FIG. 3 shows schematically the generation of a control signal for controlling a controllable device on the basis of the impedance values measured or determined by the impedance measuring device 10. Evaluation means 15 are attached downstream of the impedance measuring device 10 for evaluating or detecting changes in the impedance values. The evaluation means 15 deliver result information RI to the generation means 17 as a result of the change in impedance value. The generating means 17 are configured to generate a control signal CTRS in dependence on the result information RI. In the present case, the result information RI is passed to the generating means 17 in the form of a digital signal or in the form of bytes, in which generating means 17 the generation of the control signal CTRS is executed with the help of a translation table 16, which will be discussed in more detail later on. It should be mentioned that the result information RI can also be formed by an analog signal.

The control signal CTRS generated by the generating means 17 is used subsequently for controlling electrical devices 19 as shown schematically in FIG. 3 for example an entertainment electronics device, especially a CD-Player, TV set or suchlike. The transmission of the control signal CTRS to the device 19 is done on the basis of an infrared (IR) signal transmission. The transmission can also be done in another manner, for example on the basis of ultrasonic signals or by means of radio frequency signals (RF) or simply in a wirebound way.

It may further be mentioned that such a controllable device can be formed by other devices, for example by an electronic light control device, where in this case the generated control signal is provided and configured for controlling an outputted light intensity of the light control device.

The translation table 16 contains, for example, a status table, in which different statuses corresponding to respective different values, of either the electrical resistance or the capacitance, determined in the evaluation means 15, are converted into control signals by the generation means 17 for control routines or switching routines in the electrical device 19.

The Table 1 given below shows such statuses or changes in status as well as the parameters linked to them, which changes in status can be achieved, for example on touching the middle finger of the right hand by the finger tips 12 of the left hand.

TABLE 1

| | Measured | Control | |
|---|---|---|---|
| Status | value in Ω | command | Action |
| A | 0 | on/off | No touching of the fingers |
| B | 40 | Volume | Touch: Middle finger of right hand |
| | | higher | with palm of left hand |
| C | 49 | Volume | Touch: Middle finger of right hand |
| | | lower | with thumb of left hand |
| D | 58 | Next | Touch: Middle finger of right hand |
| | | channel | with index finger of left hand |
| E | 67 | Previous | Touch: Middle finger of right hand |
| | | channel | with small finger of left hand |
| F | 76 | Pause/Play | Touch: Middle finger of right hand |
| | | | with middle finger of left hand |

From the above table may be concluded, for example, that different resistance values can be attained by touching the tip 11 of the middle finger of the right hand by individual tips 12 of the fingers of the left hand, which resistance values are assigned to certain control commands using the above Table 1.

Instead of such an assignment on touching different finger tips, for example, a volume control, brightness control or the like can be effected by again moving the tip 11 of the middle finger of the right hand with continuous skin contact along the longitudinal direction of a finger or between the defined points 13 in the palm of the left hand as shown in FIG. 2, because there is a change in impedance and thus, for example, in the determinable resistance value, resulting from a relative movement of the tip 11 of the middle finger of the right hand relative to the fingers and/or the palm of the left hand. Thus, such a change in the resistance value can be used directly in terms of volume control, brightness control or the like, while in this case several control signals are generated and outputted in the generating means 17.

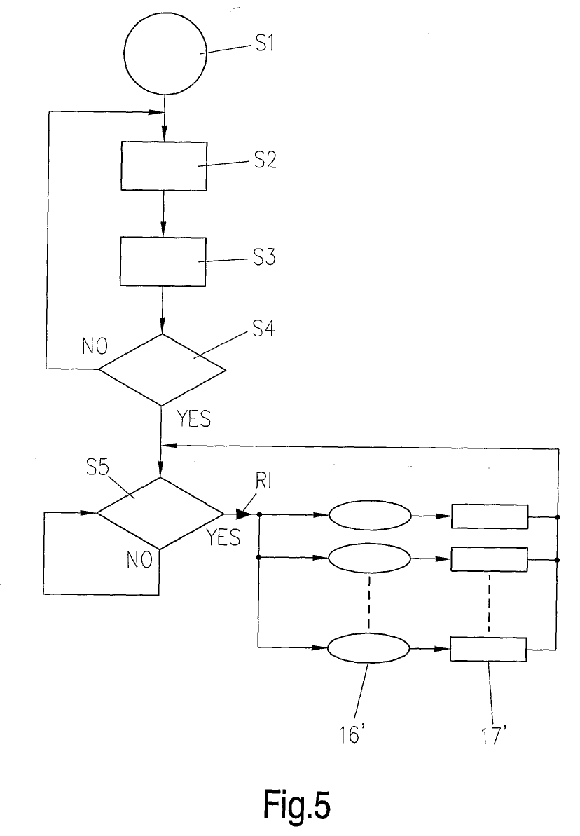

It can be generally noted that the absolute values of the measured impedance of different users are different, so that more advantageous difference values between individual measuring points are used for conversion into a control signal, especially a remote control signal. This can be effected by appropriate subtractive switching or by calibrating to a zero value before use, which initial value is set in correlation with a corresponding basic setting or initial setting of the device to be controlled, wherein such a balancing routine or calibration routine is explained further with the help of FIG. 5.

FIG. 4 shows a converted arrangement of the definition especially of the detection electrode 6, in which instead of an arrangement of the detection electrodes 6 in the area of the wrist or underarm area, the detection electrodes 6 are arranged in the area of the middle finger of the hand of the arm 2 in this case. It may be mentioned that the detection electrodes 6 can be integrated in a ring that can be put on the middle finger.

Otherwise, it should be noted at this point that a change in the sides, i.e. placement of the current source electrodes 5 and detection electrodes 6 on the respective other arm or the other hand of the user is to be regarded as an equivalent initial situation.

A flowchart concerning the execution of the method as invented as well as an additionally provided calibration or balancing is depicted in FIG. 5, which calibration will be explained in detail below. The method as invented is based on the system shown in the FIG. 1 or 2 and FIG. 3.

In step S1 there is a switching on, in which the current source electrodes 5 are simultaneously supplied with power, where for example the constant AC current mentioned above is fed through an electrically conducting first connection, which first connection was established to a first body area 3a, and an electrically conducting second connection, which second connection was established to a second body area 3b at a distance from the first body area 3a. In addition, determination of the impedance value of the impedance is done between a third body area 4a established by an electrically conducting third connection and a fourth body area 4b established by an electrically conducting fourth connection.

In a subsequent step S2, a first setting routine is carried out, in which the user for example sits or stands and the right arm 1 and the left arm 2 or particularly the fingers or palms of the hands must not touch. A touching of predefined neighboring areas of the underarms or hands having the current source electrodes 5 as well as the detection electrodes 6, that is to say a change in the physical relation between at least one body part of the whole body, and the whole body is effected in a subsequent step S3 in a second setting routine upon a command or signal not further specified, which change in the physical relation results in a change in the impedance value of an impedance between the third body area 4a contacted through the third contact 6a and the fourth body area 4b contacted through the fourth contact 6b. For example, in the present case, the tip of the right middle finger 11 touches the tip of the left middle finger 12 for a calibration or balancing. In both these actions, a change in the impedance value of the impedance between the third body area 4a contacted through the third contact 6a and the fourth body area 4b contacted through the fourth contact 6b is now detected with the help of the impedance measuring device 10 and stored as a reference value.

In a subsequent step S4, a review or query is executed whether the setting routine or calibration routine was executed successfully. If it was not (NO), that is to say no differences in the impedance values can be detected in the touches in step S3, the system returns to step S2. If the calibration routine was executed successfully (YES), the sequence is continued to a step 5. It may be mentioned that before returning to the step 2, the user can be informed through a suitable message in a display that there may be an incorrect attachment of the current source electrodes 5 and/or the detection electrodes 6.

The change in the impedance value against the stored reference value of the impedance is effected in step S5 with the help of the impedance measuring device 10 and the evaluation means 15. The system is, so to say, in an operating mode and reacts to actions of the user, that is here to a reciprocal touching of the fingers and/or palms of the hands. If no changes are detected in step S5 (NO), the step S5 is repeated. If changes are detected in step S5 (YES), a control of the electrical device 19 is effected by using the values in the translation table 16, that is Table 1 in the present case, and the generating means 17. The evaluation means 15 feed result information RI to the generating means 17 as a result of the change in the impedance value, whereas in the present case resistance values are delivered as result information RI. In the routine shown in FIG. 5, this routine is thus continued in a schematically depicted step 16′ in dependence on the resistance value and in dependence on the resistance value different a control signal CTRS is subsequently generated and delivered in a respective next step 17′ with the help of the generating means 17.

It may be mentioned that the current source electrodes 5 and/or the detection electrodes 6 can also be arranged or fixed on other body parts of a user and consequently other body areas can be contacted, so that such a system after possibly necessary adaptation can be used by, for example, physically handicapped persons, who without any help cannot use the usual remote controls owing to, for example, handicapped upper limbs.

It can further be observed that with an arrangement of detection electrodes 6 relatively close to each other, the difference values, such as can be obtained from a touching by different finger tips 11, 12 are enlarged as regards impedance, so that a more precise assessment is possible.

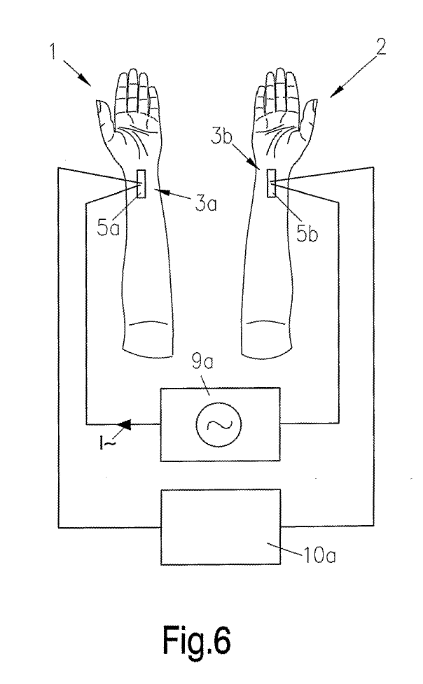

FIG. 6 shows a system as invented according to another example of embodiment, in which an electrically conducting first contact 3a is provided in the underarm area of the left arm 2 on the inner side of the underarm area and an electrically conducting second contact 3b in the underarm area of the right arm 1 on the inner side of this underarm area, by means of which first contact 3a an electrically conducting first connection is established to a first body area of said underarm area and by means of which second contact 3b an electrically conducting second connection is established to a second body area of said underarm area. Furthermore, a constant current source 9a is provided, which constant current source 9a is connected to the first contact 3a and the second contact 3b and supplies a constant AC current I˜ to these contacts. Furthermore, a high-Ohmic voltage meter 10a is connected to the first contact 3a and the second contact 3b. The system as shown in FIG. 6 is provided for determining a bioelectrical impedance or changes in this impedance based on a change in the physical relation between at least one body part (1, 2) of the whole body and the whole body. Not shown is a generation of control signals based on established changes in the impedance; reference is made in this context to the description with the help of FIG. 3 and FIG. 5. It should be mentioned that the constant current source 9a and the voltage meter 10a for measuring the bioelectrical impedance can have a structure as described in document U.S. Pat. No. 6,292,690 B1 “Apparatus and method for measuring bioelectric impedance”, Petrucelli et al, which is referred to in FIG. 1A of this document U.S. Pat. No. 6,292,690 B1 and its publication is taken to be incorporated hereby reference.

It may further be mentioned that instead of the measured resistance values in Ohms indicated in Table 1 by way of example, also the capacitance or difference values of the capacitance on contact of different body areas or the impedance values can be determined and subsequently assessed and used for generating a control signal, for example, a remote control signal.

In another embodiment of the method and system as invented, it is further provided that measured impedance values be determined on the basis of AC currents with respective different frequencies, so that a more precise determination of the impedance values is advantageously possible and consequently a more reliable control of the controllable device is possible. An arrangement for measuring a bioelectrical impedance based on three alternating currents at different frequencies is described in the patent document U.S. Pat. No. 6,532,384 B1 “Bioelectrical impedance measuring method and body composition measuring apparatus”, Fukuda, in which the publication in this context, as described under the steps S6 and S7 of FIG. 5 of said document, is taken as expressly incorporated hereby reference.

In another embodiment of the method and system as invented, an improvement can be achieved in the measuring precision, if the measures of the improvement described in the patent document U.S. Pat. No. 6,631,292 B1 “Bio-electrical impedance analyzer; RJL Systems, Inc.” are taken. The publication in this context of said patent document U.S. Pat. No. 6,631,292 B1 is taken to be incorporated herein.

1. A method for generating at least one control signal for controlling a controllable device, comprising:
establishing at least an electrically conducting first connection to a first body area of the whole body of a living being;
establishing at least an electrically conducting second connection to a second body area of the whole body of the living being, at a distance from the first body area;
making a change in the physical relation between at least one body part of the whole body and the whole body, the change in the physical relation causing a change in the impedance value of an impedance, the impedance being present between the first body area and the second body area;
carrying out a detection of the change in the impedance value of said impedance in which result information is obtained as a result of the occurrence of the change; and
carrying out a generation of the at least one control signal in relation to the result information.

2. A method as claimed in claim 1, further comprising providing a constant AC current into the first body area and into the second body area for the detection of the change, wherein the detection of the change in the impedance value of said impedance is effected between the first body area and the second body area.

3. A method as claimed in claim 1, wherein at least an electrically conducting third connection is established to a third body area of the whole body, and at least an electrically conducting fourth connection is established to a fourth body area of the whole body.

4. A method as claimed in claim 3, further comprising providing a constant AC current into the first body area and into the second body area, wherein the change in the impedance value of the impedance is detected between the third body area and the fourth body area.

5. A method as claimed in claim 4, wherein the third connection and the fourth connection are established in an underarm area and/or at a finger of the hand of an arm of a human being and the first connection and the second connection are established in the underarm area and/or at a finger of the hand of the other arm of the human being, and the change in the physical relation is effected by a contact of at least one finger of the hand of the one arm with at least one finger of the hand of the other arm.

6. A method as claimed in claim 4, wherein the change in the physical relation results from one finger tip of the hand of the one arm making contact with individual finger tips of the hand of the other arm and/or being moved along the longitudinal stretch of at least one finger or predominantly transverse to the longitudinal stretch of a finger in the area of the palm of the hand of the other arm.

7. A method as claimed in claim 1, in wherein a balancing or calibration of the value of the impedance is carried out before the at least one control signal is generated.

8. A system for generating at least one control signal for controlling a controllable device, comprising:
at least an electrically conducting first contact for establishing at least an electrically conducting first connection to a first body area of a whole body of a living being;
at least an electrically conducting second contact for establishing at least an electrically conducting second connection to a second body area of the whole body of the living being at a distance from the first body area;
detection means for detecting a change in the impedance value of an impedance, the impedance being present between the first body area and the second body area, the change in the impedance value being the result of a change in the physical relation between at least one body part of the whole body and the whole body and results in result information; and
generating means for generating the control signal in dependence on the result information.

9. A system as claimed in claim 8, wherein the detection means are formed by a constant current source and a voltage meter, such that a constant AC current can be fed into the first body area and into the second body area using the constant current source (9a) for detecting the change, and the change in the impedance value of said impedance can be detected between the first body area and the second body area by the voltage meter (10a).

10. A system as claimed in claim 8, comprising at least an electrically conducting third contact for establishing at least an electrically conducting third connection to a third body area of the whole body of the living being, and at least an electrically conducting fourth contact for establishing at least an electrically conducting fourth connection to a fourth body area of the whole body of the living being.

11. A system as claimed in claim 10, wherein the detection means are formed by a current source and an impedance measuring device, the current source being configured as a constant current source such that it is possible to feed a constant AC current into the first body area through the first contact and into the second body area through the second contact, wherein the change in the impedance value of the body area can be detected between the third body area and the fourth body area using the impedance measuring device (10).

12. A system as claimed in claim 10, wherein the first connection and the second connection can be established to an underarm area and/or a finger of the hand of the one arm of a human being and the third connection and the fourth connection to an underarm area and/or a finger of the hand of the other arm of a human being and the change in the physical relation is effected by a contact of at least one finger of the hand of the one arm with at least one finger of the hand of the other arm.

13. A system as claimed in claim 8, further comprising calibration means for carrying out a calibration or balancing of the impedance value before the control signal is generated.

14. A system as claimed in claim 8, wherein at least one of the contacts is integrated in a band-shaped element to be positioned on the body area.

15. (canceled)

16. (canceled)
